(19) United States
(12) Patent Application Publication
(10) Pub. No.: US 2002/0076854 A1
(43) Pub. Date: Jun. 20, 2002

(54) System, method and apparatus for constructing a semiconductor wafer-interposer using B-Stage laminates

(76) Inventor: John L. Pierce, Dallas, TX (US)

Correspondence Address: Daniel J. Chalker, Gardere Wynne Sewell L.L.P., 3000 Thanksgiving Tower, 1601 Elm Street, Dallas, TX, 75201-4761, US

(21) Appl. No.: 09/738,193

(22) Filed: Dec. 15, 2000

(51) Int. Cl. H01L 21/44; H01L 21/48; H01L 21/50; H01L 23/02; H01L 23/52

(52) U.S. Cl. 438/118; 438/106; 438/612; 257/678; 257/778

(57) ABSTRACT

The present invention provides a number of apparatus and methods for interfacing semiconductor wafers containing a multitude of semiconductor dies, with testing equipment. A substrate is constructed with a B-Stage laminate, and when attached to a semiconductor wafer, greatly improves the processing of semiconductor dies. This allows several manufacturing steps to be eliminated and thus results in improved first pass yields, decreased manufacturing times, and improved cycle times. Additionally, the use of the wafer-interposer enables testing, such as parametric and burn-in, at the wafer level. The use of the B-stage laminate also eliminates the need to produce an extremely flat interposer to match well with the very flat semiconductor wafer.

### FIELD OF THE INVENTION

The present invention relates generally to the field of integrated circuits, and more particularly, to a system, method and apparatus for constructing a semiconductor wafer-interposer using B-stage laminates.

### BACKGROUND OF THE INVENTION

The three stages of semiconductor device manufacture are wafer fabrication, assembly and testing. The testing stage always includes an evaluation of the electrical connections within the device, and often includes burn-in testing as well. In a conventional manufacturing process, the semiconductor wafer is diced into individual semiconductor dies, and the dies are assembled into packages. The packages can be either the permanent type, for dies that are designed to be wire bonded into their packages, or they can be temporary, for chips that are designed to be mounted via flip-chip techniques. The purpose of the package is to protect the semiconductor die as well as provide connections that allow the package to be attached to a testing apparatus or printed circuit board. The fact that e final testing of the individual dies does not take place until the dies have been packaged, increases the cost. This increased cost stems from the greater complexity and size required of the testing apparatus, as well as the difficulty of manipulating large quantities of separately packaged dies.

In addition to the tooling and labor costs associated with electrical and burn-in testing of individually packaged dies, there is also the wasted expense of packaging the dies that will subsequently be found to be defective. Since in a conventional process all dies must be packaged before final testing is done, this means that all defective die will necessarily be packaged, and the expense of doing so is complete waste. For example, if 6%, a conservative estimate, of the dies fail either the electrical or burn-in testing, then 60 die packaging operations are wasted for every 1000 dies that are produced. The ability to test the dies before the packaging operations would obviously reduce production costs.

The savings associated with a wafer level testing protocol are multifold. In addition to the savings associated with the elimination of unnecessary packaging operations, inventory carrying costs are reduced because the processing cycle times are reduced since “good” dies are identified earlier in the manufacturing process.

Accordingly, there is a need for a wafer-interposer and a method that allows for the testing of semiconductor dies while still assembled in wafer form. It is also important that the wafer-interposer and method does not impede the ability to package, or directly mount the dies after they have passed the testing, and have been cut from the wafer. Additionally, a wafer-interposer that compensates for surface imperfections related to the semiconductor wafer and eliminates the need to produce an extremely flat interposer is desired.

### SUMMARY OF THE INVENTION

The present invention provides a substrate that can be combined with a semiconductor wafer to form a wafer-interposer that can be used to test semiconductor die prior to dicing or singulating. This allows several manufacturing steps to be eliminated and thus results in improved first pass yields, decreased manufacturing times, and improved cycle times. Additionally, the use of the wafer-interposer enables testing, such as parametric and burn-in, at the wafer level. Eliminating the need to singulate and package the dies before testing results in a significant cost avoidance opportunity for chip manufacturers. The fact that the use of the wafer-interposer accomplishes all of this while providing cost effective packaging is another substantial benefit of the present invention. The use of the B-stage adhesive substrate also eliminates the need to produce an extremely flat interposer to match well with the very flat semiconductor wafer.

The present invention provides, in one form, a substrate comprising a B-Stage laminate or adhesive material and having an upper and a lower surface. The substrate has one or more first electrical contacts on the lower surface, and one or more second electrical contacts on the upper surface. The second electrical contacts have greater surface area and greater pitch than the first electrical contacts. One or more first electrical pathways pass through the substrate and connect the first electrical contacts to the second electrical contacts.

Another form of the present invention provides a substrate and semiconductor wafer assembly having a substrate comprised of a B-Stage laminate or adhesive material, a semiconductor wafer and a layer of no-flow underfill disposed between the substrate and the semiconductor wafer. The substrate has an upper and a lower surface, one or more first electrical contacts on the lower surface, and one or more second electrical contacts on the upper surface. The second electrical contacts have a greater surface area and greater pitch than the first electrical contacts. In addition, one or more first electrical pathways pass through the substrate and connect the first electrical contacts to the second electrical contacts. The semiconductor wafer includes one or more semiconductor dies, and has a first and a second surface. The semiconductor wafer also has one or more third electrical contacts on the first surface, the third electrical contacts being associated with the semiconductor dies. A conductor electrically connects each of the first electrical contacts with a corresponding third electrical contact.

Yet another form of the present invention provides a method for producing a semiconductor wafer-interposer. One or more first electrical contacts are attached to the lower surface of a substrate comprising a B-Stage adhesive material. One or more second electrical contacts are attached to an upper surface of the substrate. The second electrical contacts have a greater surface area and greater pitch than the first electrical contacts. One or more first electrical pathways are created to pass through the substrate and connect the first electrical contacts to the second electrical contacts.

In still another form, the present invention provides a method for producing a wafer-interposer assembly. One or more first electrical contacts are attached to the lower surface of a substrate comprising a B-Stage adhesive material. One or more second electrical contacts are attached to an upper surface of the substrate. The second electrical contacts have greater surface area and greater pitch than the first electrical contacts. One or more first electrical pathways are created to pass through the substrate and connect the first electrical contacts to the second electrical contacts. A conductor is deposited on one or more third electrical contacts on an upper surface of a semiconductor wafer. The semiconductor wafer includes one or more semiconductor dies and the third electrical contacts are associated with the semiconductor dies. A layer of no-flow underfill is applied to the upper surface of the semiconductor wafer. The substrate is aligned with the semiconductor wafer so that the conductors on the third electrical contacts of the semiconductor wafer correspond to the first electrical contacts on the lower surface of the substrate. The substrate is then attached to the semiconductor wafer.

### BRIEF DESCRIPTION OF THE DRAWINGS

The above and further advantages of the invention may be better understood by referring to the following description in conjunction with the accompanying drawings in which corresponding numerals in the different figures refer to the corresponding parts in which:

FIG. 1 is an exploded view of a wafer testing interposer and semiconductor die in accordance with the present invention;

FIG. 2 shows the upper surface of a substrate in accordance with the present invention;

FIG. 3 is a cross section of a semiconductor wafer prepared for bonding to a wafer testing interposer in accordance with the present invention;

FIG. 4 shows the top of a semiconductor die that has had some of the electrical contacts redistributed in accordance with the present invention;

FIG. 5 is a cross section of a substrate and semiconductor wafer, each mounted on a flat surface in preparation for being affixed to one another in accordance with the present invention;

FIG. 6 is a cross section of a substrate and semiconductor wafer, each mounted on a flat surface, after they have been affixed to one another in accordance with the present invention; and

FIGS. 7A and 7A are cross sections showing before and after images of the substrate and semiconductor wafer being affixed to one another in accordance with the present invention.

### DETAILED DESCRIPTION

While the making and using of various embodiments of the present invention are discussed herein in terms of a wafer testing interposer and semiconductor wafer assembly apparatus and method, it should be appreciated that the present invention provides many inventive concepts that can be embodied in a wide variety of contexts. The specific embodiments discussed herein are merely illustrative of specific ways to make and use the invention, and are in no way meant to limit the scope of the invention.

The present invention provides a substrate that can be combined with a semiconductor wafer to form a wafer-interposer that can be used to test semiconductor die prior to dicing or singulating. This allows several manufacturing steps to be eliminated and thus results in improved first pass yields, decreased manufacturing times, and improved cycle times. Additionally, the use of the wafer-interposer enables testing, such as parametric and burn-in, at the wafer level. Eliminating the need to singulate and package the dies before testing results in a significant cost avoidance opportunity for chip manufacturers. The fact that the use of the wafer-interposer accomplishes all of this while providing cost effective packaging is another substantial benefit of the present invention. The use of the B-stage adhesive substrate also eliminates the need to produce an extremely flat interposer to match well with the very flat semiconductor wafer.

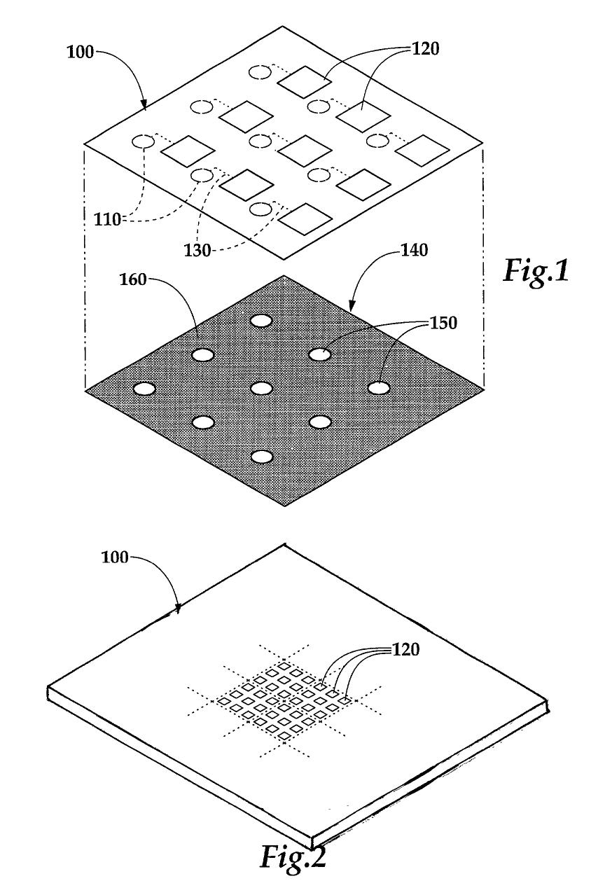

The general features of the substrate for the wafer-interposer of the present invention are shown in FIG. 1. The substrate 100 comprises a B-Stage laminate or adhesive material, and is shown suspended above a semiconductor die 140. The first electrical contacts 110 are shown in outline as they are on the lower surface of the substrate 100. The first electrical pathways 130 connect the first electrical contacts 110 to the second electrical contacts 120, which are on the upper surface of the substrate 100. The first and second electrical contacts 110 and 120 can be connection pads. The substrate 100 is then mounted on a semiconductor wafer. FIG. 1 shows only a portion of the substrate 100, and only a portion of the semiconductor wafer, i.e. a single semiconductor die 140. Deposits of a conductor 150 are applied to the third electrical contacts, which may be connection pads, on the dies that are included in the semiconductor wafer. The conductor 150 can be any conductive adhesive. Examples include, but are not limited to, solder balls, conductive-polymer containing adhesives, and conductive plastics. A layer of no-flow underfill 160 is applied to the first surface of the semiconductor wafer (and dies 140).

FIG. 2 shows a larger view of the top of a substrate 100 according to the present invention. The second electrical contacts 120 are show as pads on the upper surface. In this depiction there are four sets of connections of nine contacts each. This would be connected to a wafer containing four dies. Clearly this is a very small number for demonstration purposes only, since actual semiconductor wafers can contain a much larger 15 number of dies.

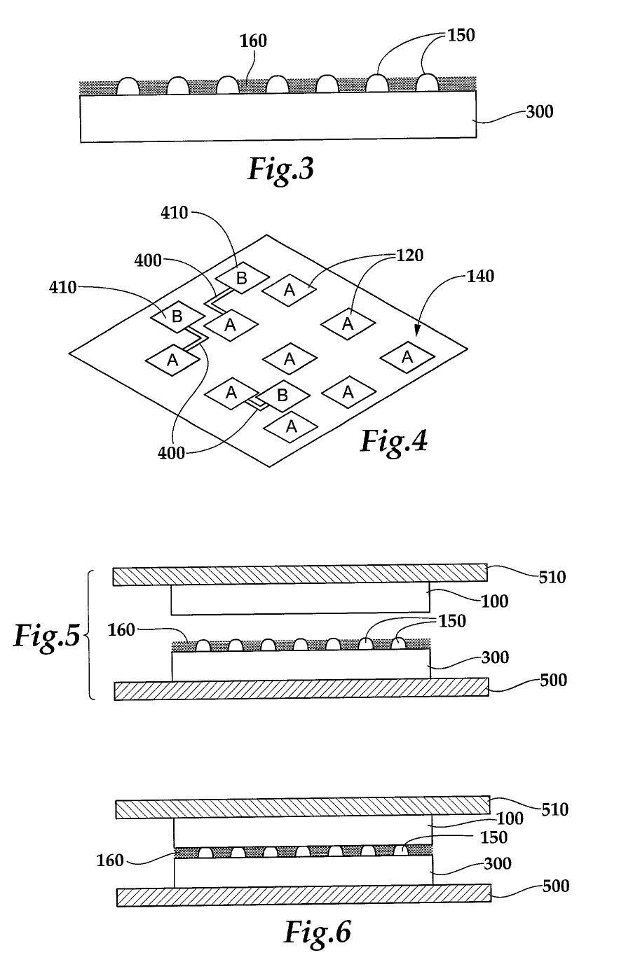

FIG. 3 shows a side view of a semiconductor wafer 300 that is prepared for attachment to a substrate 100 (FIG. 2). The deposits of the conductors 150 are shown, while the remaining surface of the semiconductor wafer 300 is covered by a layer of underfill 160. The underfill 160 is used to stabilize the assembly by resisting any lateral forces caused 20 by differences in the rates of thermal expansion between the semiconductor wafer 300 and the substrate 100 (FIG. 2). The underfill 160 is applied over the entire semiconductor wafer 300, but it is not immediately cured.

As shown in FIG. 1, the location of the second electrical contacts 120 on the upper surface of the substrate 100 can be redistributed. In other words, the position of the second electrical contacts 120 need not correspond directly to the position of the first electrical contacts 110. As an alternative, the relocation can take place on the surface of the semiconductor wafer (or die 140) as shown in FIG. 4. In FIG. 4 some of the third electrical contacts have been redistributed from their original locations (A) to different locations (B), by the application of additional metalization prior to depositing the conductors 150 (FIG. 3) and the underfill 160 (FIG. 3).

FIG. 5 shows a substrate 100 and a semiconductor wafer 300 prior to being attached to each other to form a wafer-interposer comprised of a substrate and semiconductor wafer assembly. At this stage, the substrate 100 still contains partially cured resins. The deposits of the conductor 150 have been applied, as has the uncured underfill 160. Prior to assembly, the semiconductor wafer 300 is placed on a flat surface 500. The substrate 100 is mounted on another flat surface 510 that has been coated with a material to prevent adhesion of the substrate 100. Suitable coating materials are known to those skilled in the art. The flat surfaces 500 and 510 can be various materials and configurations. The primary requirement for the surfaces 500 and 510 is that they be substantially as planar as the semiconductor wafer 300. A mechanism to bring the two surfaces 500 and 510 together is not shown, but would be known to those skilled in the art. Alignment of the semiconductor wafer 300 and the substrate 100 is accomplished by the use of split vision optics or any other comparable system. Prior to forming the assembly, the surface 510 can be heated to increase the malleability of the substrate 100. The heating can be by accomplished by using forced air, heating coils, or any other method known in the industry.

FIG. 6 shows the semiconductor wafer 300 and the substrate 100 after they have been brought together to form an assembly. To insure that 100% of the electrical contacts are formed between the deposits of the conductors 150 and the first electrical contacts 110 on the lower surface of the substrate 100, the entire assembly is compressed. For example, if the conductors 150 are solder balls whose nominal height is 0.006 inches, then the first surface of the semiconductor wafer 300 and the lower surface of the substrate 100 could be brought to within 0.005 inches to insure proper contact. This would compensate for any variations in planarity of the surfaces or in the height of the conductors 150.

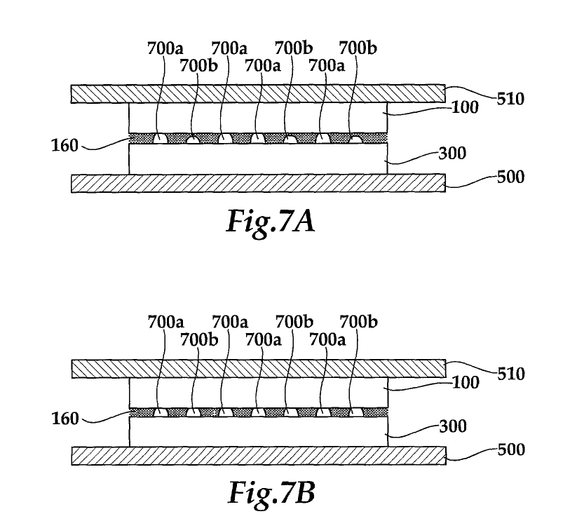

FIGS. 7A and 7B show the effects of compression. Before compression, conductors 700a make contact with the semiconductor wafer 100; whereas conductors 700b do not make contact with the semiconductor wafer 100. If the assembly were cured at this stage there would be missing connections. However, following compression, all contacts are properly made, as depicted in the FIG. 7B. In order for compression to work, the conductors 700a and 700b need to be able to expand when they are compressed. The fact that the underfill 160 has not yet been cured allows this to happen.

After the constituent parts are joined, the wafer-interposer assembly is cured. This can be accomplished while the compression is occurring, or after the assembly is removed from the flat surfaces 500 and 510. During the curing process the B-Stage laminate or adhesive of the substrate 100, the conductors 150 and the underfill 160 are cured. As a result, the conductors 150, 700a and 700b form permanent contacts with the third electrical contacts on the lower surface of the substrate 100. The B-Stage laminate or adhesive may form a rigid, semi-rigid or compliant bond.

All semiconductor die 140 (FIG. 1) on the semiconductor wafer 300 (FIG. 7) can now be burned-in and electrically tested prior to dicing the semiconductor wafer 300. The semiconductor dies are tested by attaching the substrate and semiconductor wafer assembly to a testing apparatus. The testing may include parametric tests or burn-in tests. In addition, the testing of the semiconductor dies can be performed in sequence, in groups or simultaneously.

The final step is to dice the wafer-interposer assembly into individual devices or circuits. The wafer-interposer assembly may also be diced into one or more semiconductor die groups. The substrate 100 for the wafer-interposer assembly forms the package for the individual semiconductor die 140 (FIG. 1). The process may also include grading one or more performance characteristics of each semiconductor die during testing and sorting the semiconductor chip assemblies based on the performance characteristics of the constituent dies. In addition, the semiconductor dies may be sorted into conforming and nonconforming groups.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the spirit and scope of the following claims. It is contemplated that the use of the present invention can involve components having different characteristics. It is intended that the scope of the present invention be defined by the claims appended hereto, giving full cognizance to equivalents in all respects.

What is claimed is:

1. An interposer comprising:
a substrate comprising a B-stage adhesive material, and having an upper surface and a lower surface;
one or more first electrical contacts on the lower surface;
one or more second electrical contacts on the upper surface, the second electrical contacts having greater surface area, and greater pitch than the first electrical contacts; and
one or more first electrical pathways passing through the substrate, and connecting the first electrical contacts to the second electrical contacts.

2. The interposer as recited in claim 1 wherein the first and second electrical contacts are connection pads.

3. A substrate and semiconductor wafer assembly comprising:
a substrate comprising a B-stage adhesive material, and having an upper surface and a lower surface, one or more first electrical contacts on the lower surface, one or more second electrical contacts on the upper surface, the second electrical contacts having greater surface area and greater pitch than the first electrical contacts, one or more first electrical pathways passing through the substrate, and connecting the first electrical contacts to the second electrical contacts.
a semiconductor wafer including one or more semiconductor dies, and having a first surface and a second surface, one or more third electrical contacts on the first surface of the semiconductor wafer, the third electrical contacts being associated with the semiconductor dies;
a conductor electrically connecting each first electrical contact with a corresponding third electrical contact; and
a layer of no-flow underfill disposed between the first surface of the semiconductor wafer and the lower surface of the substrate.

4. The substrate and semiconductor wafer assembly as recited in claim 3 wherein the first, second and third electrical contacts are connection pads.

5. The substrate and semiconductor wafer assembly as recited in claim 3 wherein each conductor is a solder ball.

6. The substrate and semiconductor wafer assembly as recited in claim 3 wherein each conductor comprises a conductive-polymer containing adhesive.

7. The substrate and semiconductor wafer assembly as recited in claim 3 wherein each conductor comprises a conductive plastic.

8. A method of producing a semiconductor wafer-interposer comprising the steps of:
attaching one or more first electrical contacts to a lower surface of a substrate comprising a B-Stage adhesive material;
attaching one or more second electrical contacts to an upper surface of the substrate, the second electrical contacts having greater surface area and greater pitch than the first electrical contacts; and
creating one or more first electrical pathways passing through the substrate and connecting the first electrical contacts to the second electrical contacts.

9. The method as recited in claim 8, wherein the first and second electrical contacts are connection pads.

10. A method for producing a wafer-interposer assembly comprising the steps of:
attaching one or more first electrical contacts to a lower surface of a substrate, the substrate comprising a B-Stage adhesive material;
attaching one or more second electrical contacts to an upper surface of the substrate, the second electrical contacts having greater surface area and greater pitch than the first electrical contacts;
creating one or more first electrical pathways passing through the substrate and connecting the first electrical contacts to the second electrical contacts;
depositing a conductor on one or more third electrical contacts on an upper surface of a semiconductor wafer, the semiconductor wafer including one or more semiconductor dies and the third electrical contacts being associated with the semiconductor dies;
applying a layer of no-flow underfill to the upper surface of the semiconductor wafer;
aligning the substrate with the semiconductor wafer so that the deposits of the conductor on the third electrical contacts correspond with the first electrical contacts on the lower surface of the substrate;
attaching the substrate to the semiconductor wafer.

11. The method as recited in claim 10 wherein the first, second and third electrical contacts are connection pads.

12. The method as recited in claim 10 further comprising the step of curing the B-Stage adhesive, the conductors, and the underfill.

13. The method as recited in claim 10 further comprising the step of applying additional metalization to one or more of the third electrical contacts to redistribute them prior to the attachment of the substrate.

14. The method as recited in claim 10 further comprising the step of adding additional metalization to one or more of the third electrical contacts to improve the contact between the conductor and the third electrical contacts.

15. The method as recited in claim 10 where in the step of attaching the substrate to the semiconductor wafer comprises the steps of:
placing the semiconductor wafer on a first flat surface and holding the semiconductor wafer in place;
coating a second flat surface with a material that will prevent adhesion of the substrate;
placing the substrate on the second flat surface and holding the substrate in place; and
bringing the first and second flat surfaces together so that the semiconductor wafer and the substrate form an adhesive bond.

16. The method as recited in claim 10 further comprising the step of singulating the substrate and semiconductor wafer assembly into one or more semiconductor die assemblies.

17. The method as recited in claim 10 wherein the cured B-Stage adhesive forms a rigid bond.

18. The method as recited in claim 10 wherein the cured B-stage adhesive forms a semi-rigid bond.

19. The method as recited in claim 10 wherein the cured B-Stage adhesive forms a compliant bond.

20. The method as recited in claim 10 wherein each conductor is a solder ball.

21. The method as recited in claim 10 wherein each conductor comprises a conductive-polymer adhesive.

22. The method as recited in claim 10 wherein each conductor comprises a conductive plastic.

23. The method as recited in claim 10 further comprising the steps:
attaching the substrate and semiconductor wafer assembly to a testing apparatus; and
testing at least one of the semiconductor dies.

24. The method as recited in claim 23 wherein the step of testing the semiconductor dies further comprises performing parametric testing on at least one of the dies.

25. The method as recited in claim 23 wherein the step of testing the semiconductor dies further comprises performing burn-in testing on at least one of the dies.

26. The method as recited in claim 23 wherein the step of testing the semiconductor dies further comprises testing the semiconductor dies in sequence.

27. The method as recited in claim 23 wherein the step of testing the semiconductor dies further comprises testing the semiconductor dies simultaneously.

28. The method as recited in claim 23 further comprising the step of grading one or more performance characteristics of each semiconductor die during testing.

29. The method as recited in claim 28 further comprising the step of singulating the substrate and semiconductor wafer assembly into one or more semiconductor die assemblies.

30. The method as recited in claim 29 further comprising the step of sorting the semiconductor die assemblies based on the one or more performance characteristics.

31. The method as recited in claim 29 further comprising the step of sorting the semiconductor die assemblies into conforming and nonconforming groups.
